(19) United States
(12) Patent Application Publication
(10) Pub. No.: US 2025/0300674 A1
(43) Pub. Date: Sep. 25, 2025

(54) PARITY-CHECK MATRIX (PCM) FOR ENCODERS AND DECODERS

(71) Applicant: NXP USA, Inc., AUSTIN, TX (US)

(72) Inventors: Rong Zhang, San Jose, CA (US); Rui Cao, Sunnyvale, CA (US); Hari Ram Balakrishnan, Chennai (IN); Sudhir Srinivasa, Los Gatos, CA (US); Hongyuan Zhang, Fremont, CA (US)

(21) Appl. No.: 18/955,274

(22) Filed: Nov. 21, 2024

(30) Foreign Application Priority Data
Mar. 25, 2024 (IN) 202441023356

(51) Int. Cl. H03M 13/11; H03M 13/00

(52) U.S. Cl. CPC H03M 13/116; H03M 13/1137; H03M 13/611

(57) ABSTRACT

One example discloses a method for encoding a message, comprising: receiving a set of message-data-bits; generating a set of parity-bits based on the set of message-data-bits; wherein the parity-bits are generated by multiplying the set of message-data-bits with a generator matrix derived from a corresponding parity-check matrix (PCM) of an LDPC code; wherein the LDPC code has a total codeword block length of 2×1944 bits; and generating an encoded message that includes both the set of message-data-bits and the set of parity-bits.

### REFERENCE TO PROVISIONAL APPLICATION TO CLAIM PRIORITY

A priority date for this present U.S. patent application has been established by prior India Patent Application, Serial No. IN202441023356, entitled “WIFI QC-LDPC Codes With Codeword Block Length 2×1944 Bits”, filed on Mar. 25, 2024, and commonly assigned to NXP USA, Inc.

The present specification relates to systems, methods, apparatuses, devices, articles of manufacture and instructions for message encoding and decoding.

### SUMMARY

According to an example embodiment, a method for encoding a message, comprising: receiving a set of message-data-bits; generating a set of parity-bits based on the set of message-data-bits; wherein the parity-bits are generated by multiplying the set of message-data-bits with a generator matrix derived from a corresponding parity-check matrix (PCM) of an LDPC code;
wherein the LDPC code has a total codeword block length of 2×1944 bits; and
generating an encoded message that includes both the set of message-data-bits and the set of parity-bits.

In another example embodiment, the LDPC code is a QC-LDPC (low-density parity-check) code.

In another example embodiment, the LDPC code with a corresponding PCM has a code rate of at least one of: 1/2, 2/3, 3/4 and 5/6.

In another example embodiment, the LDPC code with a corresponding PCM has a 1/2 code rate; and the corresponding PCM of the code is as shown in at least one of: FIG. 3A, FIG. 3B, FIG. 3C, or FIG. 3D.

In another example embodiment, the LDPC code with a corresponding PCM has a 2/3 code rate; and the corresponding PCM of the code is as shown in at least one of: FIG. 4A, FIG. 4B, FIG. 4C, FIG. 4D, or FIG. 4E.

In another example embodiment, the LDPC code with a corresponding PCM has a 3/4 code rate; and the corresponding PCM of the code is as shown in at least one of: FIG. 5A, FIG. 5B, FIG. 5C, or FIG. 5D.

In another example embodiment, the LDPC code with a corresponding PCM has a 5/6 code rate; and the corresponding PCM of the code is as shown in at least one of: FIG. 6A, FIG. 6B, FIG. 6C, FIG. 6D, or FIG. 6E.

According to an example embodiment, a method for generating a parity-check matrix (PCM) for encoding a message, comprising: receiving a 1×1 codeword subblock from a first parity-check matrix (PCM) of a first LDPC code; and generating a 2×2 codeword subblock for a second PCM of a second LDPC code from the 1×1 codeword subblock from the first PCM.

In another example embodiment, the first PCM of the first LDPC code has a total block length of 1944 bits; and the second PCM of the second LDPC code has a total block length of 2×1944 bits.

In another example embodiment, generating includes performing a diagonal or off-diagonal expansion of each 1×1 codeword subblock of the first PCM into a 2×2 codeword subblock.

In another example embodiment, the 2×2 codeword subblock is a final 2×2 codeword subblock; and generating includes, expanding the 1×1 codeword subblock into a diagonal 2×2 codeword subblock; and expanding the 1×1 codeword subblock into an off-diagonal 2×2 codeword subblock.

In another example embodiment, measuring a girth of a new LDPC code with a PCM consisting of a set of 2×2 codeword subblocks, each using either diagonal or off-diagonal expansion method; and selecting a PCM consisting a set of 2×2 codeword subblocks as the final PCM for a LDPC code if the girth of the PCM with one set of 2×2 codeword subblocks is greater than the girth of another PCM with another set of 2×2 codeword subblocks, and if not, then selecting another PCM with another set of 2×2 codeword subblock as the final PCM.

In another example embodiment, measuring a number of short cycles of a new LDPC code with a PCM consisting of a set of 2×2 codeword subblocks, each using either diagonal or off-diagonal expansion method; and selecting a PCM consisting a set of 2×2 codeword subblocks as the final PCM for a LDPC code if the number of short cycles of the PCM with one set of 2×2 codeword subblocks is less than the number of short cycles of another PCM with another set of 2×2 codeword subblocks, and if not, then selecting another PCM with another set of 2×2 codeword subblock as the final PCM.

In another example embodiment, measuring an error correction metric of a new LDPC code with a PCM consisting of a set of 2×2 codeword subblocks, each using either diagonal or off-diagonal expansion method; and selecting a PCM consisting a set of 2×2 codeword subblocks as the final PCM for a LDPC code if the error correction metric of PCM with one set of 2×2 codeword subblock is better than the error correction metric of another PCM with another set of 2×2 codeword subblock, and if not, then selecting another PCM with another set of 2×2 codeword subblock as the final PCM.

According to an example embodiment, a method for decoding a message, comprising: receiving an encoded message that includes a set of message-data-bits and a set of parity-bits; wherein the parity-bits were generated by multiplying the set of message-data-bits with a set of codewords from a generator matrix derived from a parity-check matrix (PCM) having a total block length of 2×1944 bits; and identifying the set of message-data-bits from the encoded message using the parity-bits.

The above discussion is not intended to represent every example embodiment or every implementation within the scope of the current or future Claim sets. The Figures and Detailed Description that follow also exemplify various example embodiments.

Various example embodiments may be more completely understood in consideration of the following Detailed Description in connection with the accompanying Drawings.

### BRIEF DESCRIPTION OF THE DRAWINGS

FIG. 1 represents an example parity-check matrix (PCM) having a 1944 bit codeword block length.

FIG. 2 represents an example parity-check matrix (PCM) having a 2×1944 bit codeword block length.

FIGS. 3A-3D represent examples of a parity-check matrix (PCM) having a 2×1944 bit codeword block length and a 1/2 code rate.

FIGS. 4A-4E represent examples of a parity-check matrix (PCM) having a 2×1944 bit codeword block length and a 2/3 code rate.

FIGS. 5A-5D represent examples of a parity-check matrix (PCM) having a 2×1944 bit codeword block length and a 3/4 code rate.

FIGS. 6A-6E represent examples of a parity-check matrix (PCM) having a 2×1944 bit codeword block length and a 5/6 code rate.

FIG. 7 represents an example system for hosting instructions for encoding and/or decoding messages using a parity-check matrix (PCM) having a 2×1944 bit codeword block length.

While the disclosure is amenable to various modifications and alternative forms, specifics thereof have been shown by way of example in the drawings and will be described in detail. It should be understood, however, that other embodiments, beyond the particular embodiments described, are possible as well. All modifications, equivalents, and alternative embodiments falling within the spirit and scope of the appended claims are covered as well.

### DETAILED DESCRIPTION

LDPC (low-density parity-check) codewords are linear error correcting encoder codewords used to provide error correction when transmitting messages through a noisy transmission channel. LDPC codewords are functionally defined by their parity-check matrix (PCM) (e.g. matrix prototypes of the PCM).

A PCM for an LDPC codeword is a matrix which describes a set of linear relations that components of a codeword must satisfy. In some examples the PCM is first randomly generated according to a set of sparsity constraints. A resulting sparse PCM. This sparse matrix is often randomly generated, subject to the sparsity optimization constraints. The LDPC can be constructed using the sparse PCM using either pseudorandom techniques or combinatorial techniques.

An encoded message is the output of an encoder and includes the original data-bits of message plus a set of parity-bits. The parity-bits are generated by multiplying the message-data-bits with the parity-check matrix (PCM) codewords. Various sets of the PCM's codeword bits are defined as either blocks or subblocks.

QC-LDPC codes are a special type of LDPC codes that are hardware friendly. Applications include wireless communications such as WiFi. Error correction using a QC-LDPC code improves as the codeword's block length increases.

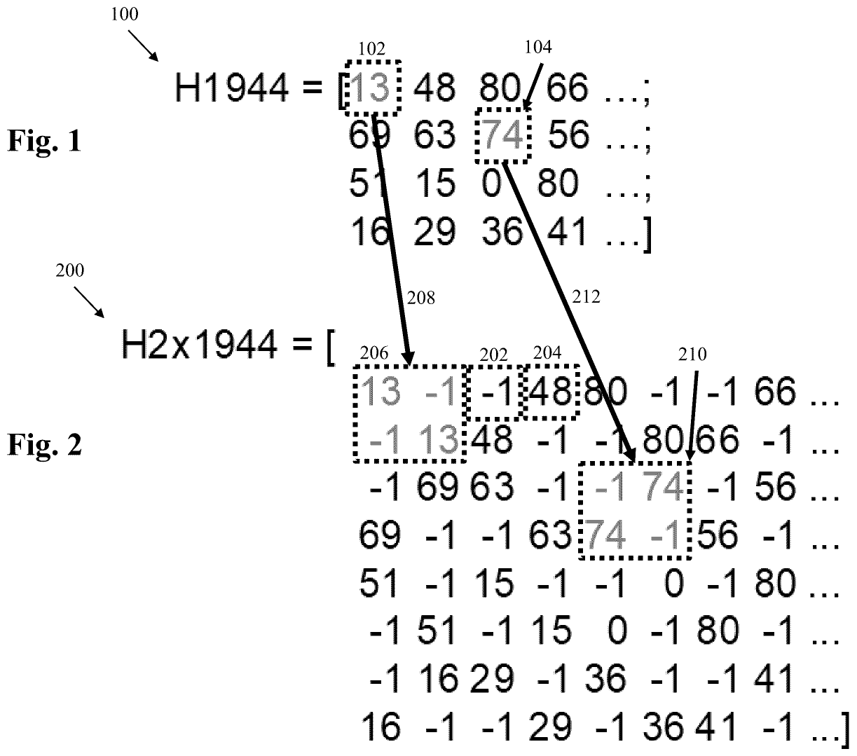

FIG. 1 represents an example 100 parity-check matrix (PCM) having a 1944 bit codeword block length. The example 1944 bit PCM 100 includes a first subblock 102 and a second subblock 104. In various example embodiments, each subblock 102, 104 includes 81 bits. Note, while only subblocks 102, 104 are individually labeled in FIG. 1, as can be seen, the example 1944 bit PCM 100 includes additional subblocks which were not individually labeled.

Now discussed are various example embodiments of a parity-check matrix (PCM) that provides more robust channel encoding for error correction. These PCMs support QC-LDPC codes having a codeword block length 2×1944 bits and code rates of 1/2, 2/3, 3/4 and 5/6.

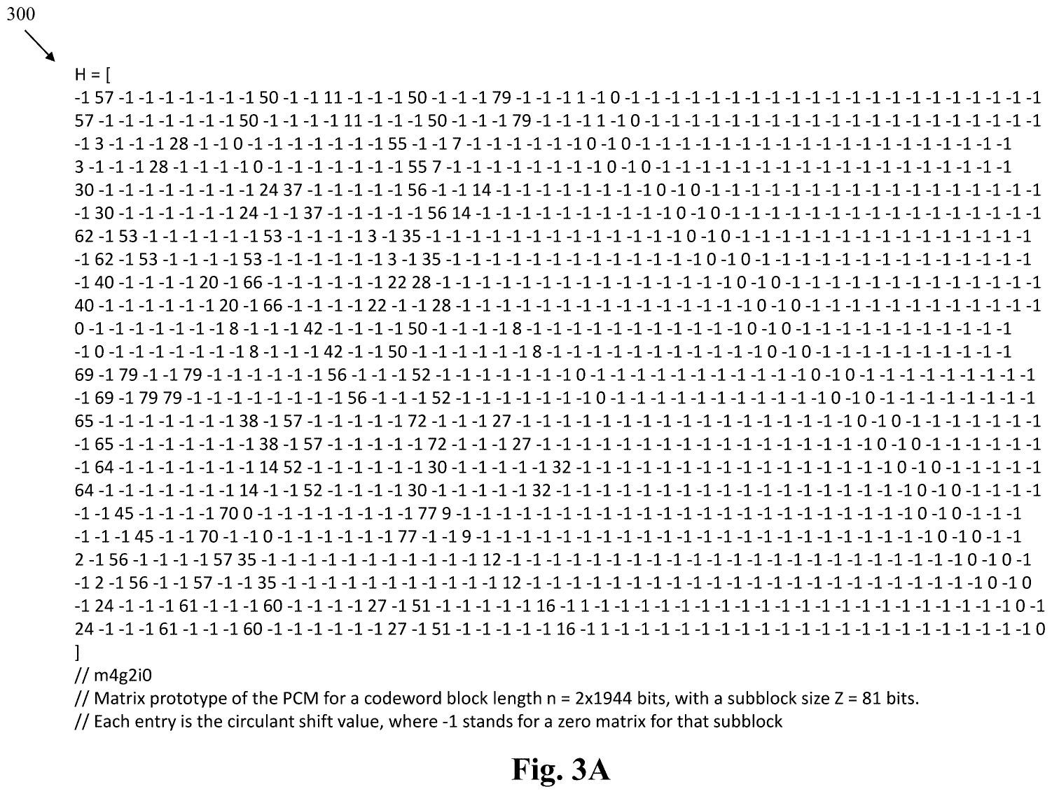

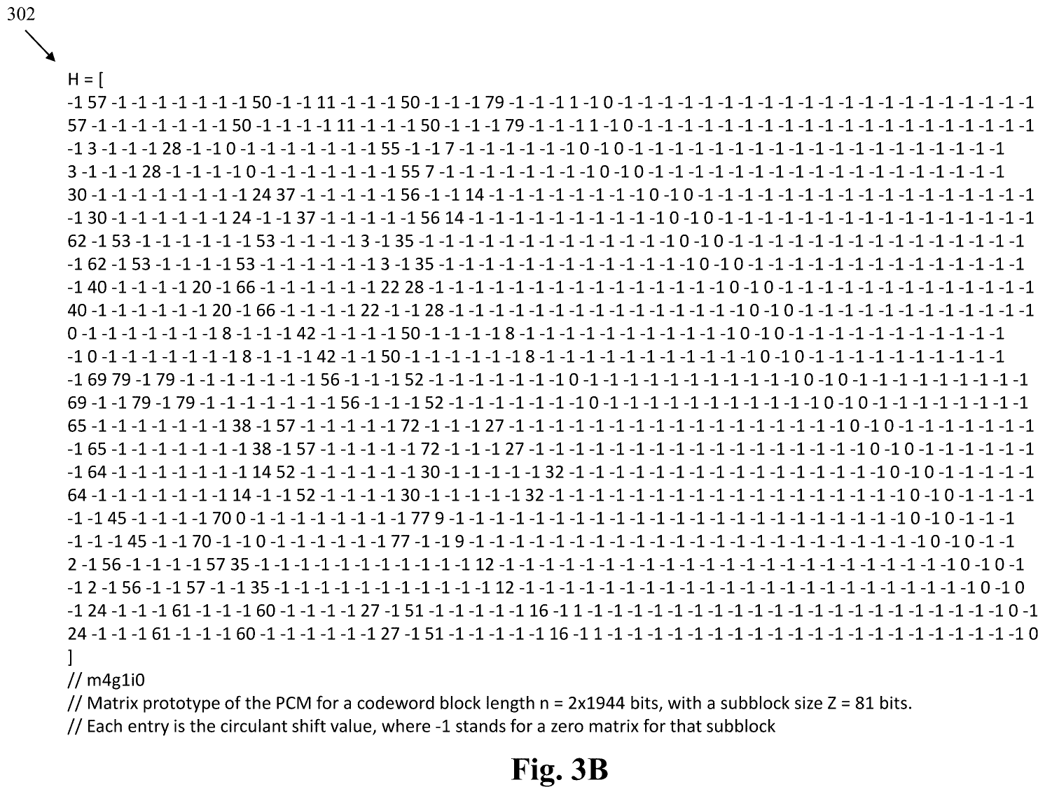

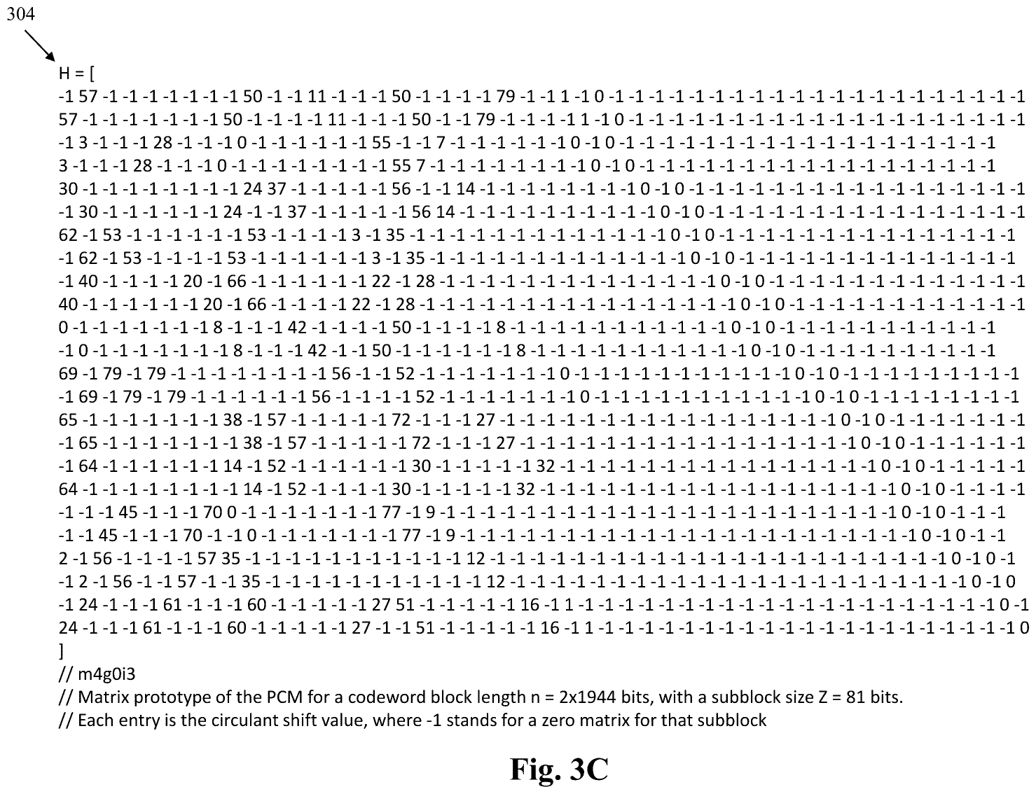

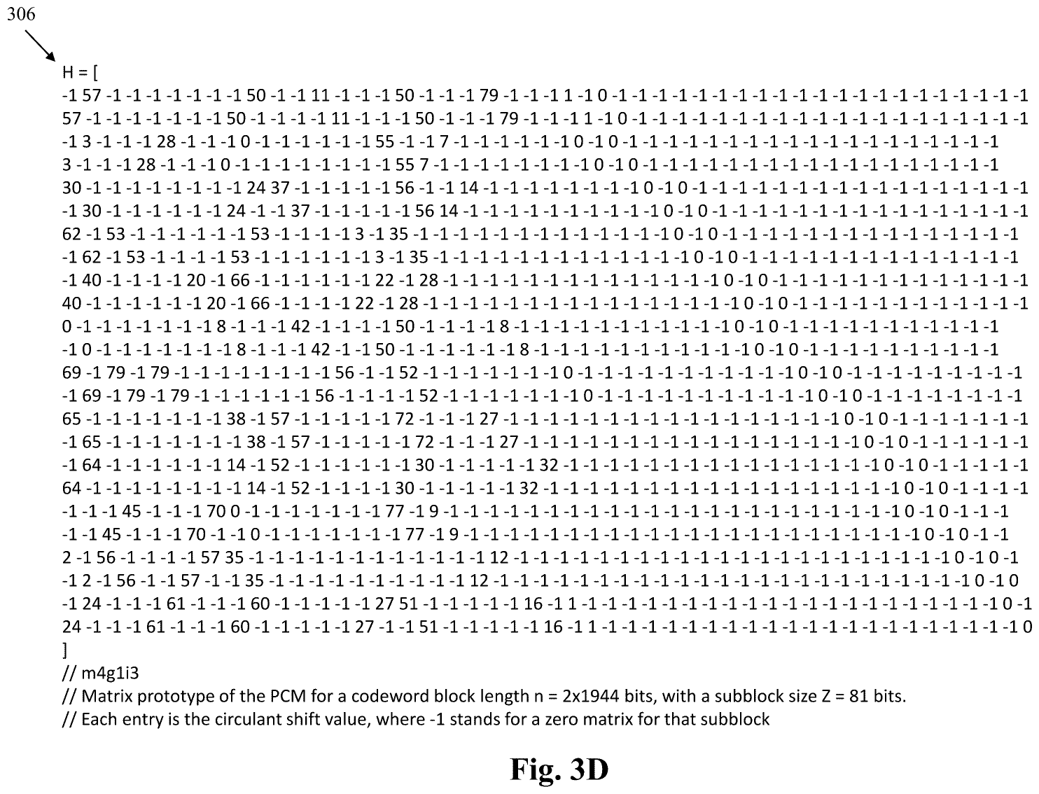

FIG. 2 represents an example 200 parity-check matrix (PCM) having a 2×1944 bit codeword block length. The example 2×1994 bit PCM 200 includes a set of subblocks 202, 204, etc., and in various example embodiments, each of these subblocks 202, 204 includes 81 bits. Note, while only subblocks 202, 204 are individually labeled in FIG. 2, as can be seen, the example 2×1944 bit PCM 200 includes additional subblocks which were not individually labeled. Complete examples of the 2×1994 bit PCM 200 are shown in FIGS. 3A through 6E.

In various example embodiments, the 2×1944 bits block length codewords are generated based on prior 1944 bits block length codewords. In some example embodiments such an approach enables reuse of existing encoding and decoding hardware (i.e. cores) that were originally used to generate the prior 1944 bits block length codewords.

One example hardware reuse approach is achieved by 2× expanding (e.g. pre-lifting) of the matrix prototypes of the PCM for the prior 1944 bits block length codewords. In some example embodiments, special constraints are imposed to facilitate and enable more efficient hardware reuse. This approach is shown in FIGS. 1 and 2 and further discussed below.

As shown in FIG. 2, a first set of subblocks 206 in the 2×1994 bit PCM 200 are derived by expanding 208 the first subblock 102 in the 1944 bit PCM 100, and a second set of subblocks 210 in the 2×1994 bit PCM 200 are derived by expanding 212 the second subblock 104 in the 1944 bit PCM 100. In other words, each 1944 bit codeword 1×1 subblock (i.e. permutation entry) within a matrix prototype of the PCM defined for codeword block length of 1944 bits is expanded (e.g. pre-lifted) 208, 212 into a 2×1944 bit codeword 2×2 subblock.

FIG. 1 shows an example matrix prototypes of a PCM defined for codeword block length of 1944 bits and code rate 5/6. The 1944 bit codeword 1×1 subblocks (i.e. permutation entry) highlighted are subblock 102 (i.e. 13) and subblock 104 (i.e. 74).

FIG. 2 shows an example of how subblock 102 (i.e. 13) is diagonally expanded (e.g. pre-lifted) 208 into the first set of subblocks 206 (i.e. 13/-1-1/13). Note that the assigned values remain 13. Similarly, FIG. 2 shows an example of how subblock 104 (i.e. 74) is off-diagonally expanded (e.g. pre-lifted) 212 into the second set of subblocks 210 (i.e. -1/74 74/-1). Note again that the assigned values remain 74.

In various example embodiments, for each transformation only diagonal or off-diagonal new subblock expansions are allowed.

To further optimise generation of the 2×1944 PCM, a progressive edge search can be performed. The progressive edge search first generates both diagonal and off-diagonal 2×2 subblocks for each 1×1 subblock. Then a girth and number of short cycles for a new 2×1944 code with a PCM consisting of one set of 2×2 subblocks expanded using one set of diagonal and off-diagonal expansion pattern of all 1×1 subblocks is determined. Finally a best expansion pattern (i.e. diagonal or off-diagonal pre-lift) is selected which maximizes girth and minimizes the number of short cycles.

Discussed another way: Step 1: transform an initial subblock into a 2× subblock using either a diagonal or a non-diagonal expansion; Step 2: test for girth size and number of short cycles; Step 3: if parity check for error correction is acceptable, then move to a next subblock and repeat the above steps; Step 4: if parity check for error correction is not acceptable, then switch from diagonal to a non-diagonal expansion. The girth and short cycle tests are performed each time all subblocks are expanded with a set of expansion pattern.

FIGS. 3A-3D represent examples 300, 302, 304, 306 of a parity-check matrix (PCM) having a 2×1944 bit codeword block length and a 1/2 code rate.

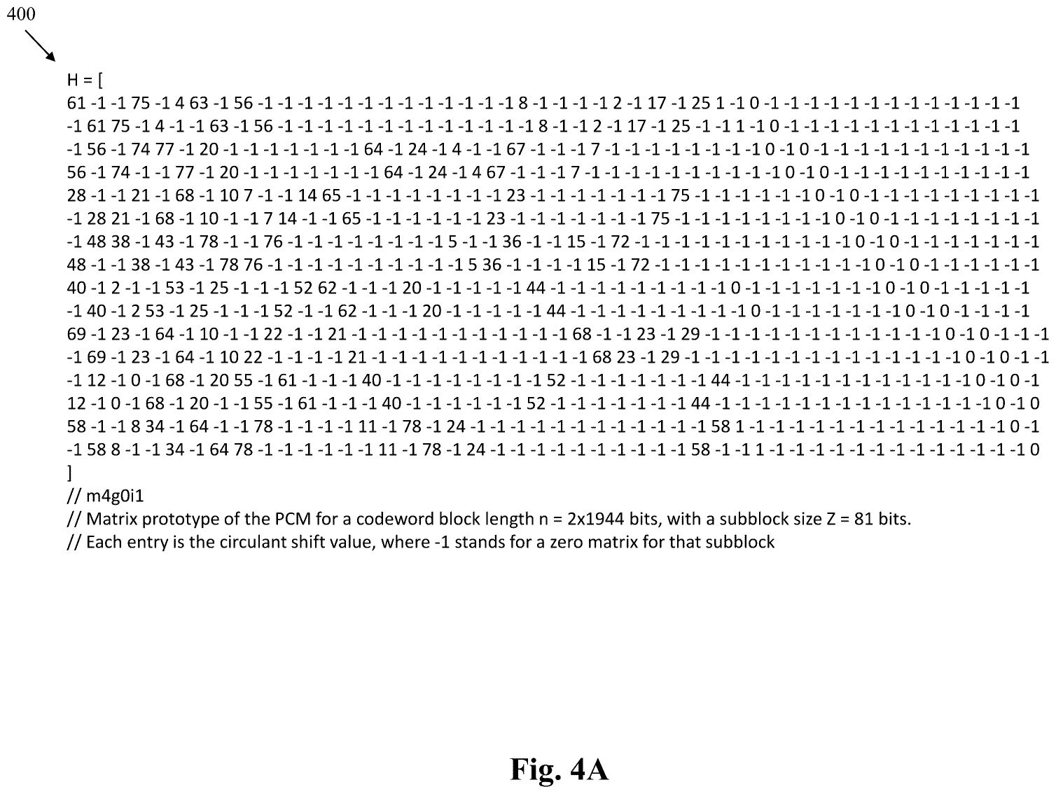

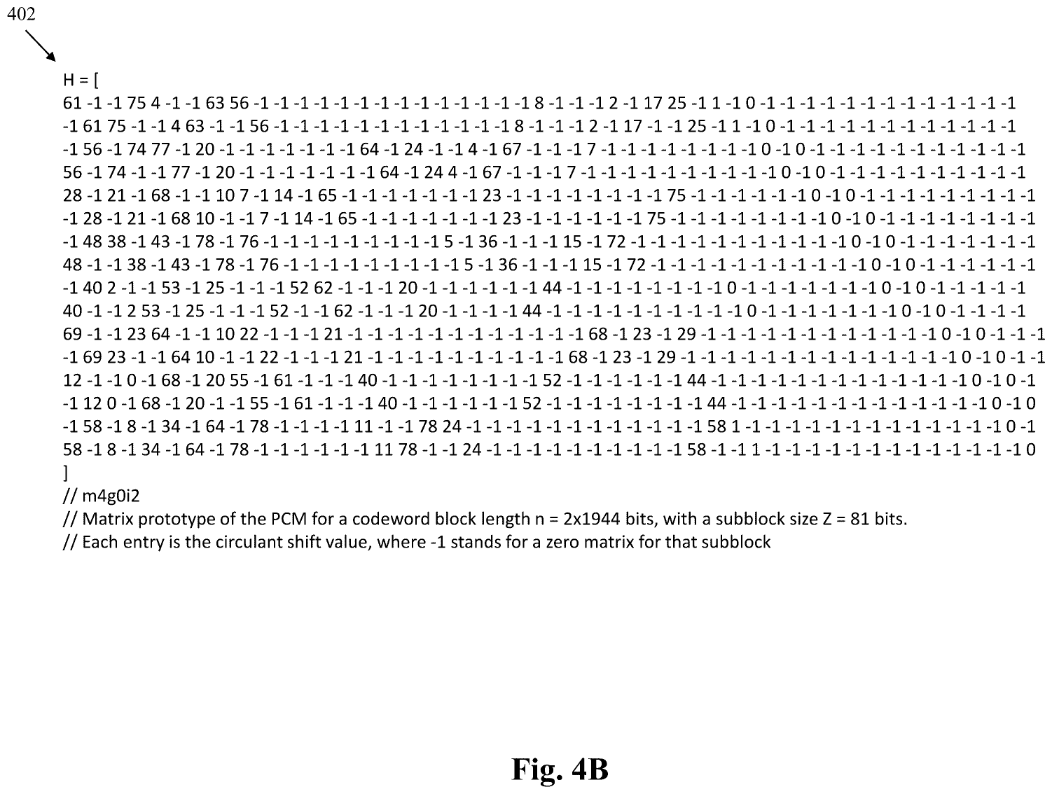

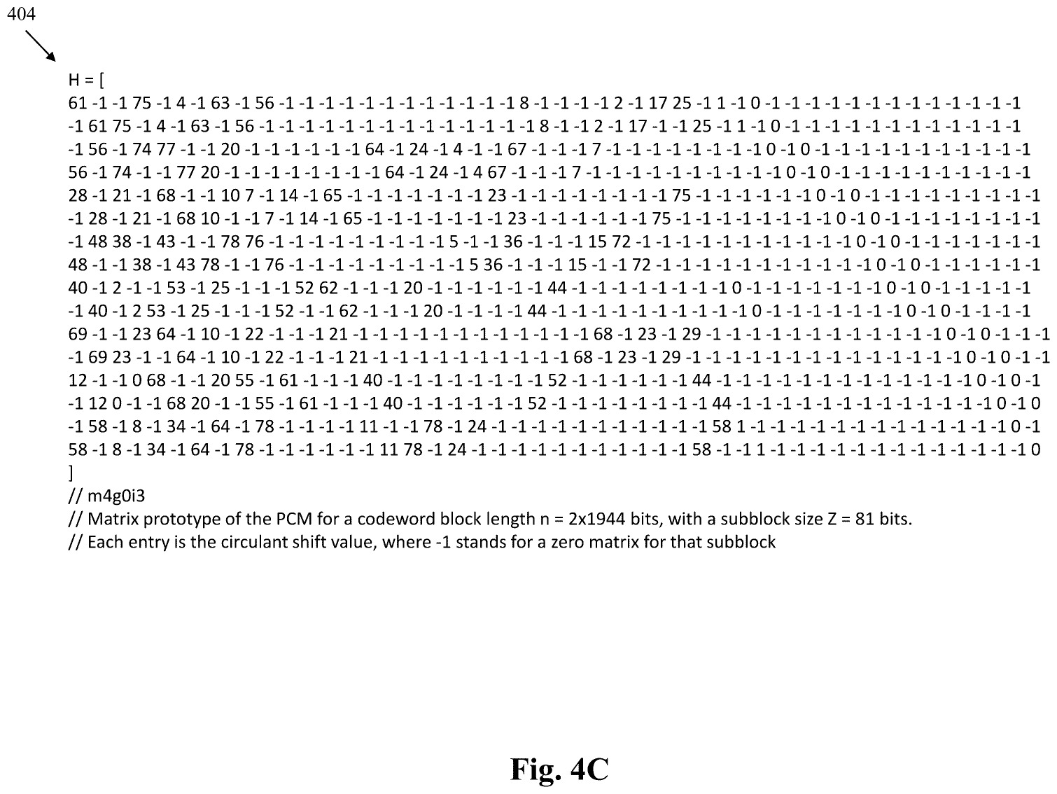

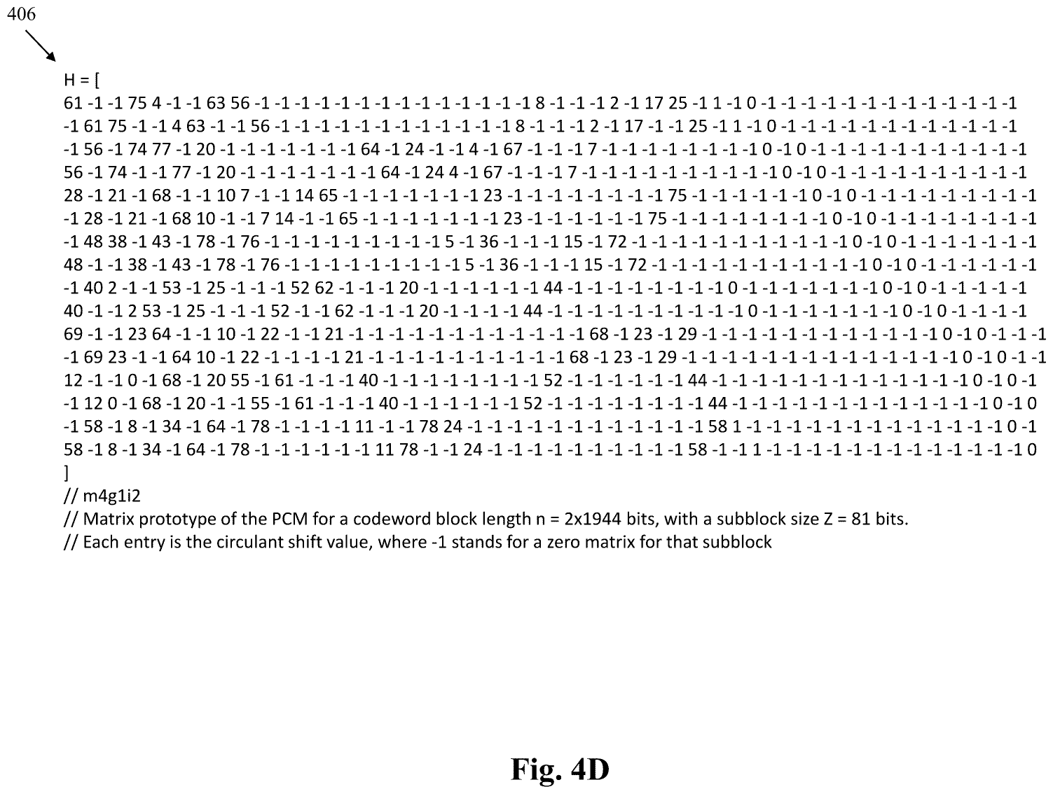

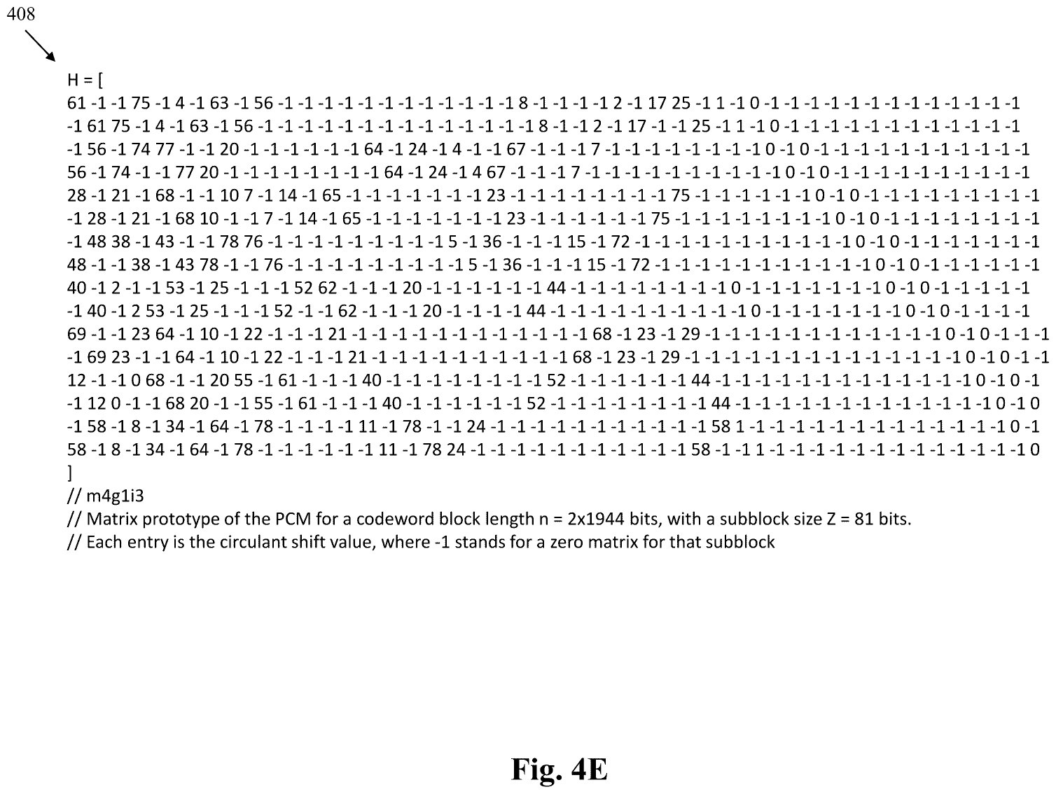

FIGS. 4A-4E represent examples 400, 402, 404, 406, 408 of a parity-check matrix (PCM) having a 2×1944 bit codeword block length and a 2/3 code rate.

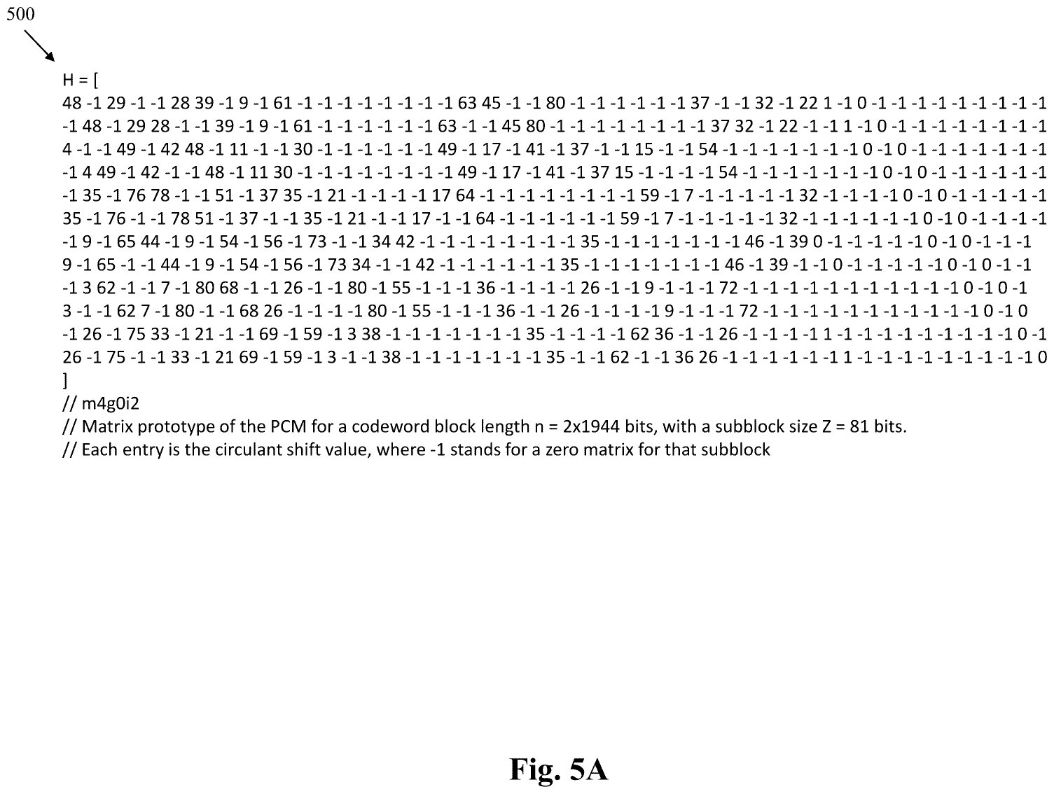

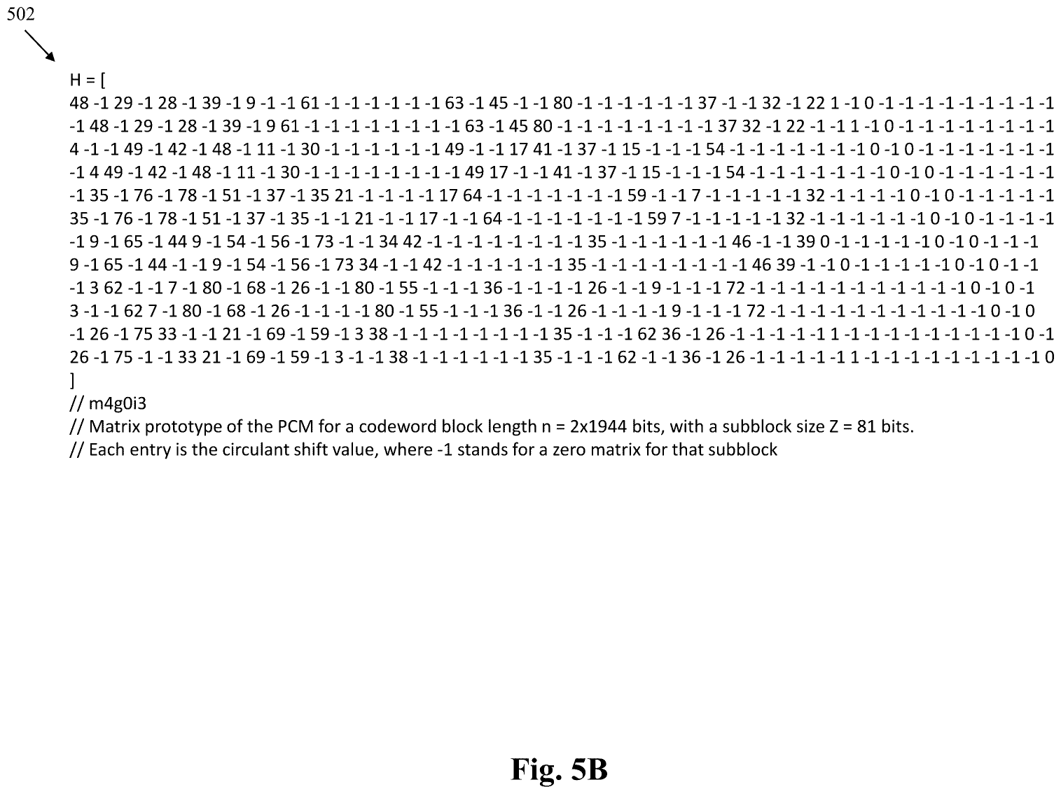

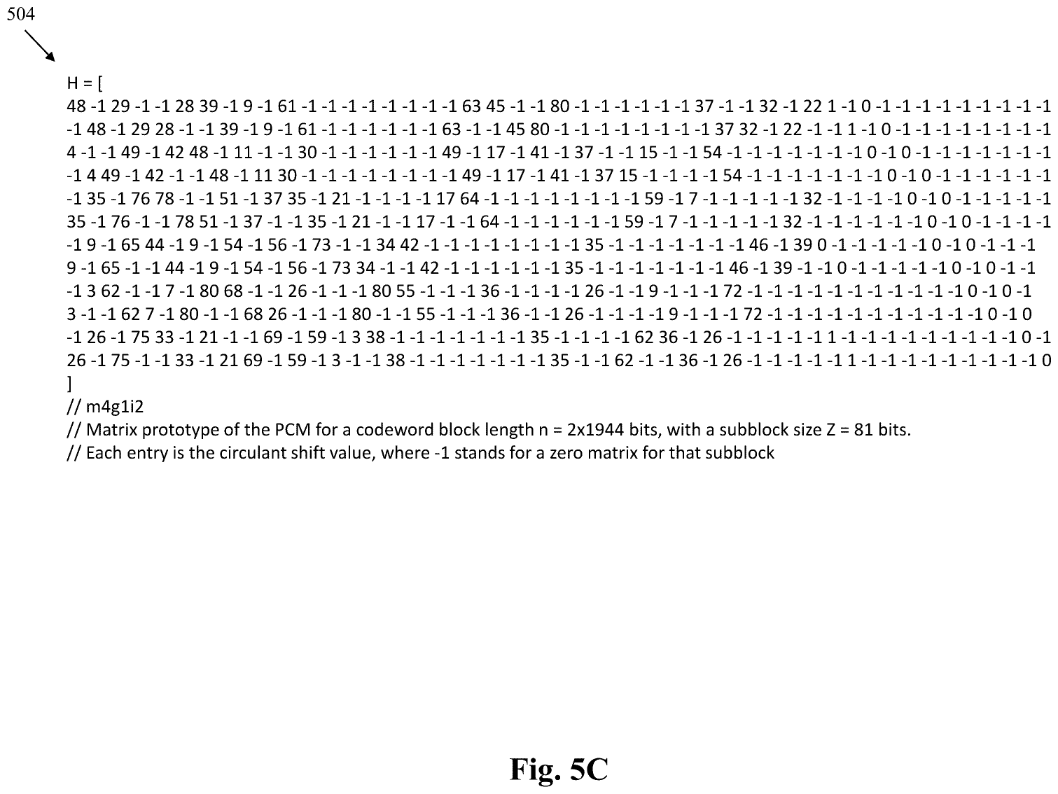

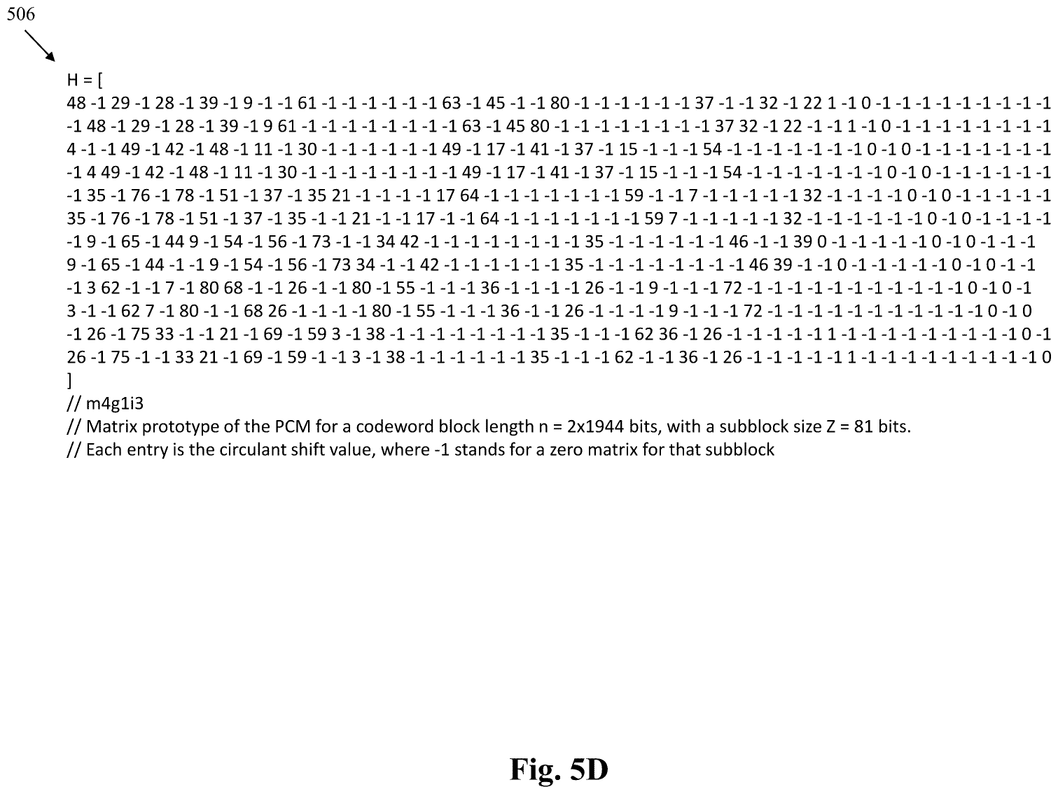

FIGS. 5A-5D represent examples 500, 502, 504, 506 of a parity-check matrix (PCM) having a 2×1944 bit codeword block length and a 3/4 code rate.

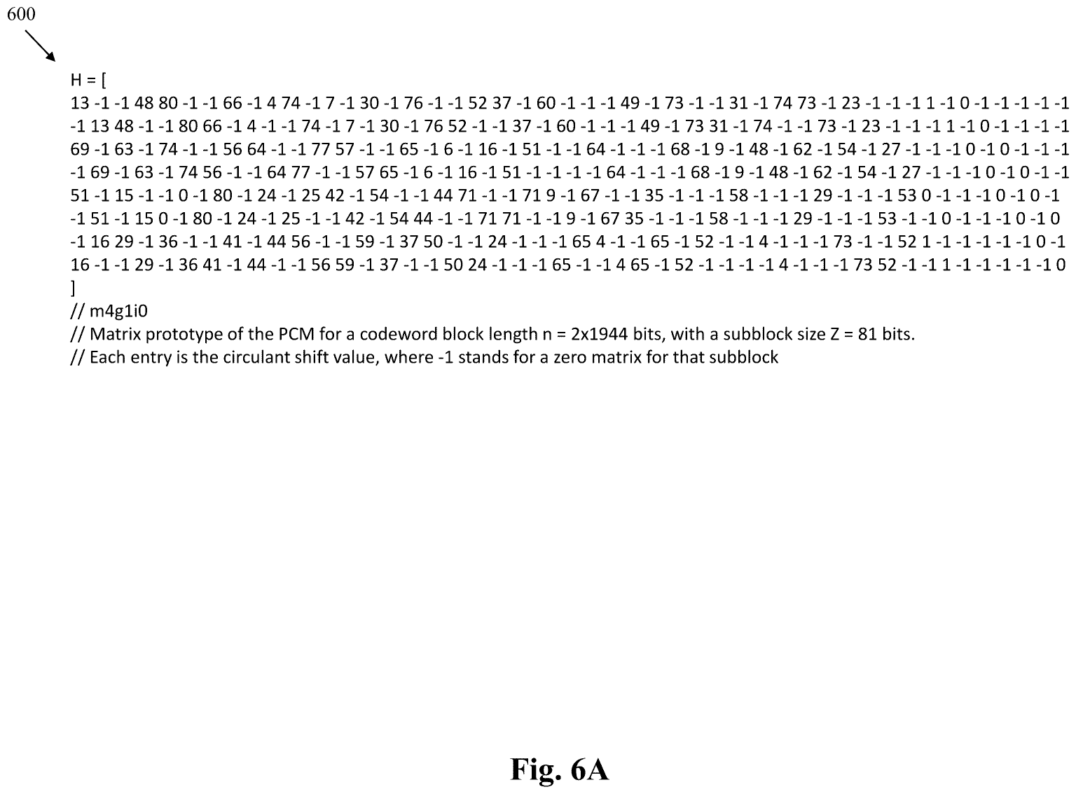

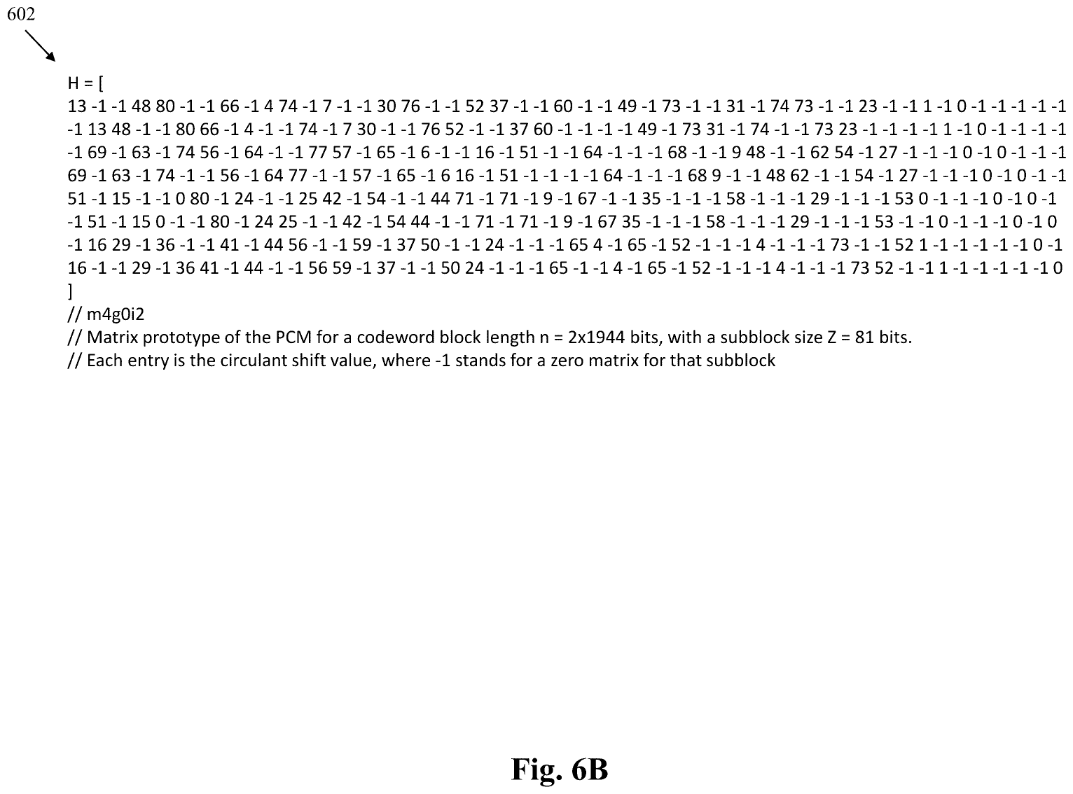

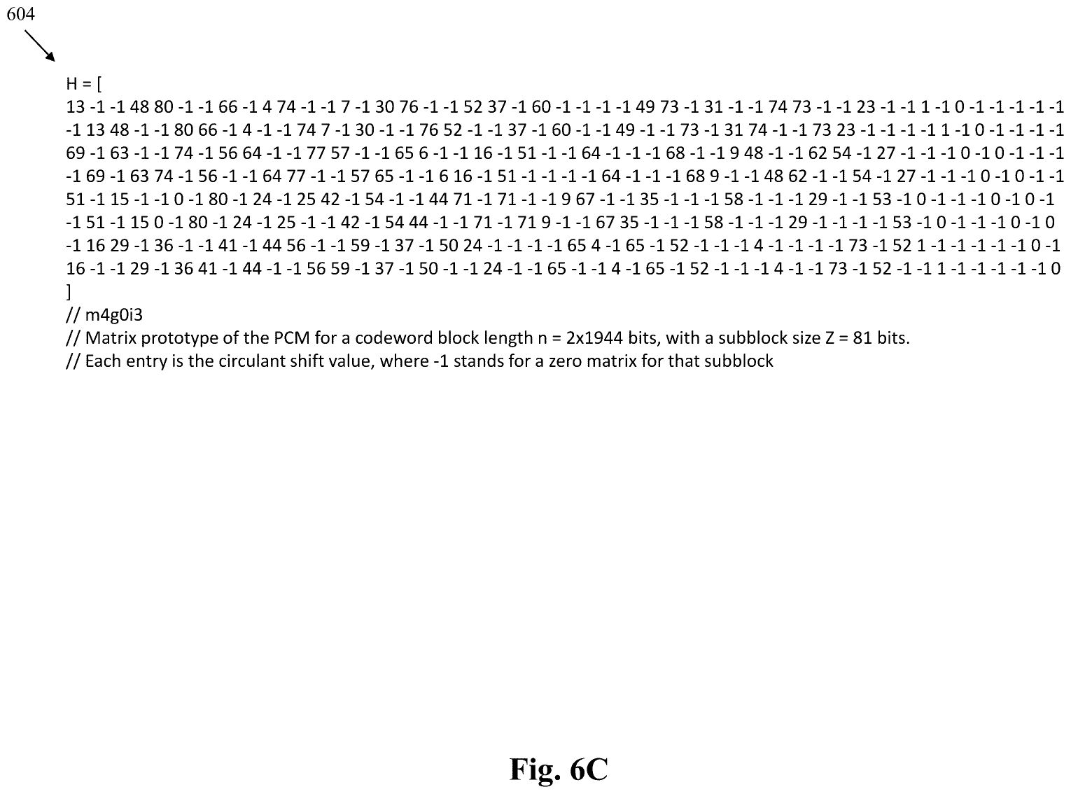

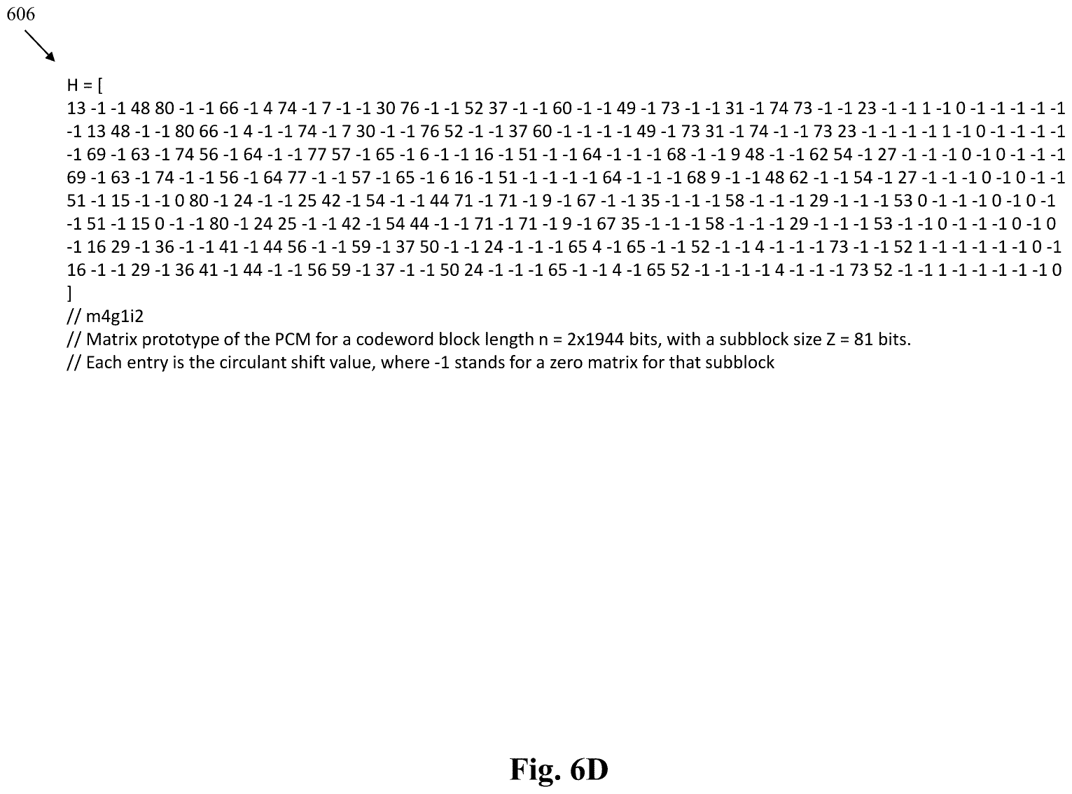

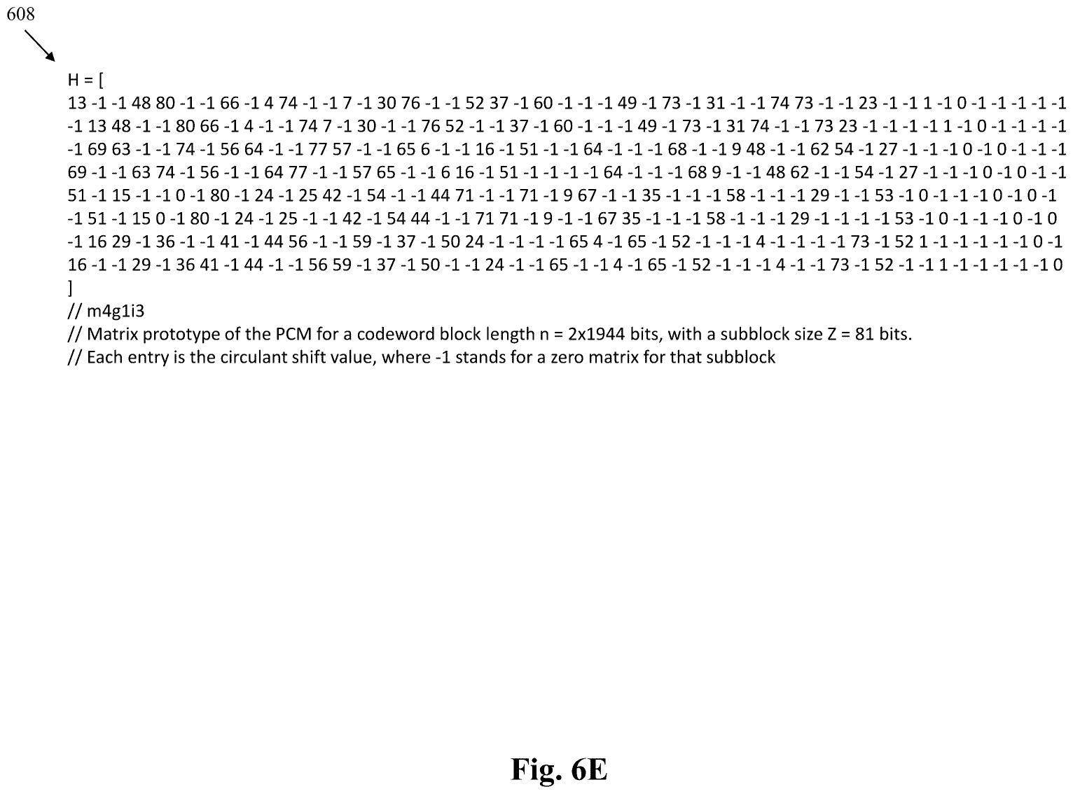

FIGS. 6A-6E represent examples 600, 602, 604, 606, 608 of a parity-check matrix (PCM) having a 2×1944 bit codeword block length and a 5/6 code rate.

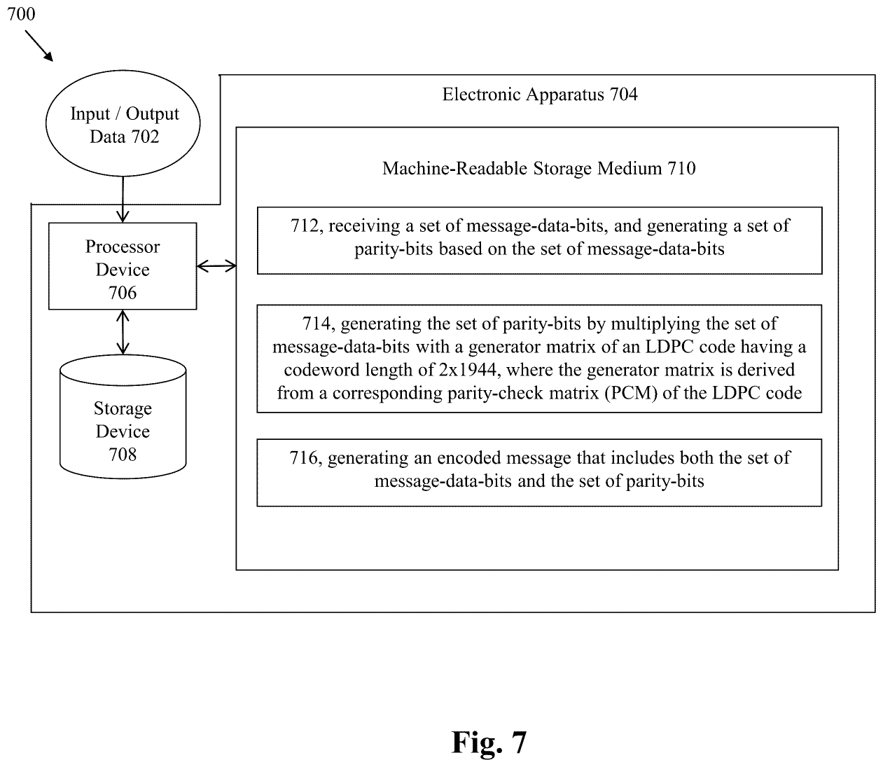

FIG. 7 represents an example system 700 for hosting instructions for encoding and/or decoding messages using a 2×1944 bit codeword with a corresponding parity-check matrix (PCM). The system 700 shows an input/output data 702 interface with a computing device 704. The computing device 704 includes a processor device 706, a storage device 708, and a non-transitory machine-readable storage medium 710. Instructions within the non-transitory machine-readable storage medium 710 control how the processor 706 interprets and transforms the input data 702, using data within the storage device 708. The non-transitory machine-readable storage medium in an alternate example embodiment is a computer-readable storage medium.

In one example, the instructions begin with 712 by receiving a set of message-data-bits, and generating a set of parity-bits based on the set of message-data-bits. In 714, generating the set of parity-bits by multiplying the set of message-data-bits with a generator matrix of an LDPC code having a codeword length of 2×1944, where the generator matrix is derived from a corresponding parity-check matrix (PCM) of the LDPC code. Then in 716, generating an encoded message that includes both the set of message-data-bits and the set of parity-bits.

The instructions/steps in the above Figures can be executed in any order, unless explicitly limited to a specific order. The reference labeling order of the instructions/steps should not be interpreted as limiting the instructions/steps to that particular reference labeling order. Also, those skilled in the art will recognize that while one example set of instructions/method has been discussed, the material in this specification can be combined in a variety of ways to yield other examples as well, and are to be understood within a context provided by this detailed description.

In some example embodiments the set of instructions described above are implemented as functional and software instructions. In other embodiments, the instructions can be implemented either using logic gates, application specific chips, firmware, as well as other hardware forms.

When the instructions are embodied as a set of executable instructions in a non-transitory computer-readable or computer-usable media which are effected on a computer or machine programmed with and controlled by said executable instructions. Said instructions are loaded for execution on a processor (such as one or more CPUs). Said processor includes microprocessors, microcontrollers, processor modules or subsystems (including one or more microprocessors or microcontrollers), or other control or computing devices. A processor can refer to a single component or to plural components. Said computer-readable or computer-usable storage medium or media is (are) considered to be part of an article (or article of manufacture). An article or article of manufacture can refer to any manufactured single component or multiple components. The non-transitory machine or computer-usable media or mediums as defined herein excludes signals, but such media or mediums may be capable of receiving and processing information from signals and/or other transitory mediums.

Example embodiments of the material discussed in this specification can be implemented in whole or in part through network, computer, or data based devices and/or services. These may include cloud, internet, intranet, mobile, desktop, processor, look-up table, microcontroller, consumer equipment, infrastructure, or other enabling devices and services. As may be used herein and in the claims, the following non-exclusive definitions are provided.

It will be readily understood that the components of the embodiments as generally described herein and illustrated in the appended figures could be arranged and designed in a wide variety of different configurations. Thus, the detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

What is claimed is:

1. A method for encoding a message, comprising:
receiving a set of message-data-bits;
generating a set of parity-bits based on the set of message-data-bits;
wherein the parity-bits are generated by multiplying the set of message-data-bits with a generator matrix derived from a corresponding parity-check matrix (PCM) of an LDPC code;
wherein the LDPC code has a total codeword block length of 2×1944 bits; and
generating an encoded message that includes both the set of message-data-bits and the set of parity-bits.

2. The method of claim 1:
wherein the LDPC code is a QC-LDPC (low-density parity-check) code.

3. The method of claim 1:
wherein the LDPC code with a corresponding PCM has a code rate of at least one of: 1/2, 2/3, 3/4 and 5/6.

4. The method of claim 1:
wherein the LDPC code with a corresponding PCM has a 1/2 code rate; and
wherein the corresponding PCM of the code is as shown in at least one of: FIG. 3A, FIG. 3B, FIG. 3C, or FIG. 3D.

5. The method of claim 1:
wherein the LDPC code with a corresponding PCM has a 2/3 code rate; and
wherein the corresponding PCM of the code is as shown in at least one of: FIG. 4A, FIG. 4B, FIG. 4C, FIG. 4D, or FIG. 4E.

6. The method of claim 1:
wherein the LDPC code with a corresponding PCM has a 3/4 code rate; and
wherein the corresponding PCM of the code is as shown in at least one of: FIG. 5A, FIG. 5B, FIG. 5C, or FIG. 5D.

7. The method of claim 1:
wherein the LDPC code with a corresponding PCM has a 5/6 code rate; and
wherein the corresponding PCM of the code is as shown in at least one of: FIG. 6A, FIG. 6B, FIG. 6C, FIG. 6D, or FIG. 6E.

8. A method for generating a parity-check matrix (PCM) for encoding a message, comprising:
receiving a 1×1 codeword subblock from a first parity-check matrix (PCM) of a first LDPC code; and
generating a 2×2 codeword subblock for a second PCM of a second LDPC code from the 1×1 codeword subblock from the first PCM.

9. The method of claim 8:
wherein the first PCM of the first LDPC code has a total block length of 1944 bits; and
wherein the second PCM of the second LDPC code has a total block length of 2×1944 bits.

10. The method of claim 8, wherein generating includes performing a diagonal or off-diagonal expansion of each 1×1 codeword subblock of the first PCM into a 2×2 codeword subblock.

11. The method of claim 8:
wherein the 2×2 codeword subblock is a final 2×2 codeword subblock; and
wherein generating includes,
expanding the 1×1 codeword subblock into a diagonal 2×2 codeword subblock; and
expanding the 1×1 codeword subblock into an off-diagonal 2×2 codeword subblock.

12. The method of claim 11, further comprising:
measuring a girth of a new LDPC code with a PCM consisting of a set of 2×2 codeword subblocks, each using either diagonal or off-diagonal expansion method; and
selecting a PCM consisting a set of 2×2 codeword subblocks as the final PCM for a LDPC code if the girth of the PCM with one set of 2×2 codeword subblocks is greater than the girth of another PCM with another set of 2×2 codeword subblocks, and if not, then selecting another PCM with another set of 2×2 codeword subblock as the final PCM.

13. The method of claim 11, further comprising:
measuring a number of short cycles of a new LDPC code with a PCM consisting of a set of 2×2 codeword subblocks, each using either diagonal or off-diagonal expansion method; and
selecting a PCM consisting a set of 2×2 codeword subblocks as the final PCM for a LDPC code if the number of short cycles of the PCM with one set of 2×2 codeword subblocks is less than the number of short cycles of another PCM with another set of 2×2 codeword subblocks, and if not, then selecting another PCM with another set of 2×2 codeword subblock as the final PCM.

14. The method of claim 11, further comprising:
measuring an error correction metric of a new LDPC code with a PCM consisting of a set of 2×2 codeword subblocks, each using either diagonal or off-diagonal expansion method; and
selecting a PCM consisting a set of 2×2 codeword subblocks as the final PCM for a LDPC code if the error correction metric of PCM with one set of 2×2 codeword subblock is better than the error correction metric of another PCM with another set of 2×2 codeword subblock, and if not, then selecting another PCM with another set of 2×2 codeword subblock as the final PCM.

15. A method for decoding a message, comprising:
receiving an encoded message that includes a set of message-data-bits and a set of parity-bits;
wherein the parity-bits were generated by multiplying the set of message-data-bits with a set of codewords from a generator matrix derived from a parity-check matrix (PCM) having a total block length of 2×1944 bits; and
identifying the set of message-data-bits from the encoded message using the parity-bits.
